(19) United States
(12) Patent Application Publication
(10) Pub. No.: US 2024/0124752 A1
(43) Pub. Date: Apr. 18, 2024

(54) ADHESIVE SHEET, LAMINATED SHEET, AND FLEXIBLE IMAGE DISPLAY DEVICE

(71) Applicant: Mitsubishi Chemical Corporation, Tokyo (JP)

(72) Inventors: Kazunobu Tada, Tokyo (JP); Masaya Minemoto, Tokyo (JP)

(73) Assignee: Mitsubishi Chemical Corporation, Tokyo (JP)

(21) Appl. No.: 18/534,412

(22) Filed: Dec. 8, 2023

Related U.S. Application Data
(63) Continuation of application No. PCT/JP2022/031911, filed on Aug. 24, 2022.

(30) Foreign Application Priority Data
Aug. 30, 2021 (JP) 2021-140191

(51) Int. Cl. C09J 133/10

(52) U.S. Cl. CPC C09J 133/10

(57) ABSTRACT

Provided is the following as an adhesive sheet having excellent flexibility at low temperature and excellent recovering ability.

An adhesive sheet formed from an adhesive composition [I]containing an acrylic polymer (A), wherein
the acrylic polymer (A) has a structural portion derived from a compound (a1) represented by (Formula 1) and a structural portion derived from a hydroxy group-containing (meth)acrylate (a2), and
the adhesive sheet has a storage shearing elastic modulus (G′) at −40° C. of not greater than 1,200 kPa,

CH₂═CH(R₁)—COO(R₂) (Formula 1)
wherein R₁ represents a hydrogen atom or a methyl group, and R₂ represents a linear or branched alkyl group having 5 to 20 carbon atoms.

### RELATED APPLICATIONS

This application is a continuation of International Application No. PCT/JP2022/031911, filed on Aug. 24, 2022, which claims priority to Japanese Patent Application No. 2021-140191, filed on Aug. 30, 2021, the entire contents of each of which are herein incorporated by reference.

### TECHNICAL FIELD

The present disclosure relates to: an adhesive sheet suitably usable for laminating a constituent member of an image display device composed of curves and a foldable and flexible image display device; a laminated sheet and flexible image display device using the adhesive sheet.

### BACKGROUND ART

In recent years, image display devices composed of curves and foldable and flexible image display devices that use an organic light-emitting diode (OLED) and a quantum dot (QD) have been developed and commercially used widely.

Such image display devices have laminate structures in which a plurality of member sheets such as a cover lens, a circularly polarizing plate, a touch film sensor, and a light-emitting element are laminated with a transparent adhesive sheet, and each of the laminate structures can be regarded as a laminated sheet in which the member sheet and the adhesive sheet are laminated.

The foldable and flexible image display device has various problems caused by interlayer stress when folded. For example, the layers may be released therebetween when folded (delamination: a phenomenon of release between the layers is called as “delamination”), and required is a laminated sheet that is not released even when folded.

In addition, required is a laminated sheet in which an effect by placing in a bent state does not remain and in which a flat state is rapidly recovered when the display is opened from a folded state.

Furthermore, repeated folding operations apply stress to the member sheets being adherends of the adhesive sheet to possibly cause cracking, finally leading to breakage. In particular, a laminated sheet durable for repeating folding operations at low temperature, which is a severer condition, is also required.

As for the foldable and flexible image display device, PTL 1, for example, discloses: an adhesive composition for a foldable display comprising a thermosetting resin and a crosslinker, wherein the thermosetting resin has a unit derived from a compound containing at least one of N or O and at least one unshared electron pair in a molecule, and the thermosetting resin has a glass transition temperature of not greater than −70° C.; an adhesive film using the same; and a foldable display comprising the same. Specifically, disclosed are: an adhesive composition for a foldable display containing a composition in which an epoxy-based crosslinker or an isocyanate-based crosslinker is added into a thermosetting resin in which carbitol acrylate, ethylhexyl acrylate, and acrylic acid are copolymerized; an adhesive film using the same; and a foldable display comprising the same.

PTL 2 and 3 focus on strain with applying a shearing force and a restoring force, and disclose an adhesive aiming to improve durability and step-following ability.

### RELATED ART DOCUMENT

### Patent Document

PTL 1: JP-A-2021-500445
PTL 2: JP-A-2020-196903
PTL 3: JP-A-2020-143284

### SUMMARY

### Problems to be Solved by the Disclosure

However, although the adhesive film disclosed in PTL 1 containing much carbitol acrylate has a small storage elastic modulus at low temperature and thereby can reduce the stress due to the folding, the above adhesive film easily relaxes the internal stress due to an internal rotation around the ether bond, and thereby the above adhesive film has a problem of a folding trace not rapidly disappearing when the folding operation is performed.

In recent years, from the viewpoint of no delamination even in use in environments at further lower temperatures and in folding at higher speed, further reduction in the storage elastic modulus at low temperature is required.

PTL 2 and 3 aim to improve durability and step-following ability, but are not about the adhesive sheet used for laminating the constituent member of the flexible image display device. PTL 2 and 3 do not consider the problems that occur with folding operation, such as specific problems of delamination and recovering ability, for example, and do not solve these problems.

The embodiment of the present disclosure relates to an adhesive sheet formed from an adhesive composition containing a (meth)acrylic polymer; and a laminated sheet in which the adhesive sheet and a member sheet are laminated. The embodiment of the present disclosure provides: an adhesive sheet and a laminated sheet used for laminating a constituent member of a flexible image display device that has excellent durability not causing delamination particularly with folding in a low-temperature state (also referred to as “low-temperature bending durability”) and that has excellent recovering ability of rapidly recovering to a flat state when the folding operation is performed (also referred to as “strain recovering ability”); and a flexible image display device using the same.

### Means for Solving the Problems

Accordingly, the present inventors have made earnest study in view of the above circumstances, and consequently found that the storage elastic modulus at low temperature becomes remarkably low, and therefore excellent flexibility and excellent recovering ability are yielded by using an adhesive sheet formed from an adhesive composition containing an acrylic polymer, wherein the acrylic polymer has a relatively long linear or branched alkyl group and a hydroxy group.

Specifically, the embodiment of the present disclosure has the following aspects.

[i] An adhesive sheet formed from an adhesive composition [I] containing an acrylic polymer (A), wherein
the acrylic polymer (A) has a structural portion derived from a compound (a1) represented by (Formula 1) and a structural portion derived from a hydroxy group-containing (meth)acrylate (a2), and
the adhesive sheet has a storage shearing elastic modulus (G′) at −40° C. of not greater than 1,200 kPa,

CH₂═CH(R₁)—COO(R₂) (Formula 1)
wherein R₁ represents a hydrogen atom or a methyl group, and R₂ represents a linear or branched alkyl group having 5 to 20 carbon atoms.
   [ii] The adhesive sheet according to [i], wherein the adhesive composition [I]contains a monofunctional (meth)acrylate (B).
   [iii] The adhesive sheet according to [i] or [ii], wherein the acrylic polymer (A) has a weight average molecular weight of 600,000 to 1,500,000.
   [iv] The adhesive sheet according to [ii] or [iii], wherein the monofunctional (meth)acrylate (B) has a glycol skeleton.
   [v] The adhesive sheet according to any one of [ii] to [iv], wherein the monofunctional (meth)acrylate (B) is a urethane (meth)acrylate.
   [vi] The adhesive sheet according to any one of [ii] to [v], wherein the monofunctional (meth)acrylate (B) is contained by 0.1 to 45 parts by weight relative to 100 parts by weight of the acrylic polymer (A).
   [vii] The adhesive sheet according to any one of [i] to [vi], wherein the adhesive composition [I] contains a photopolymerization initiator (C).
   [viii] The adhesive sheet according to any one of [i] to [vii], further comprising n-octyl (meth)acrylate.
   [ix] The adhesive sheet according to any one of [i] to [viii], wherein the adhesive sheet has a biomass degree of not less than 40%.
   [x] The adhesive sheet according to any one of [i] to [ix], wherein the adhesive sheet has a storage shearing elastic modulus at −40° C. G′(−40° C.) of not greater than 1,000 kPa.
   [xi] The adhesive sheet according to any one of [i] to [x], wherein the adhesive sheet has a storage shearing elastic modulus at 60° C. G′(60° C.) of not less than 1 kPa and not greater than 100 kPa.
   [xii] The adhesive sheet according to any one of [i] to [xi], wherein the adhesive sheet has a ratio of a storage shearing elastic modulus at −40° C. G′(−40° C.) to a storage shearing elastic modulus at −20° C. G′(−20° C.), G′(−40° C.)/G′(−20° C.), of not greater than 15.
   [xiii] The adhesive sheet according to any one of [i] to [xii], wherein the adhesive sheet has a ratio of a storage shearing elastic modulus at −40° C. G′(−40° C.) to a storage shearing elastic modulus at 60° C. G′(60° C.), G′(−40° C.)/G′(60° C.), of not greater than 200.
   [xiv] The adhesive sheet according to any one of [i] to [xiii], wherein the adhesive sheet has a glass transition temperature (Tg) of not higher than −35° C., the glass transition temperature (Tg) being defined by a maximum value of a loss tangent (Tan δ) obtained by measuring a dynamic viscoelasticity.
   [xv] The adhesive sheet according to any one of [i] to [xiv], wherein the adhesive sheet has a recovering rate of not less than 75%, the recovering rate being calculated from a remained strain value at 10 minutes after applying shearing strain corresponding to a seven-fold thickness at 25° C. to the adhesive sheet with keeping for 10 minutes and then removing a stress.
   [xvi] The adhesive sheet according to [xv], wherein the adhesive sheet has the recovering rate of not less than 80%.
   [xvii] The adhesive sheet according to any one of [i] to [xvi], wherein the adhesive sheet has a gel fraction of 30 to 95 wt. %.
   [xviii] The adhesive sheet according to any one of [i] to [xvii], wherein the adhesive sheet is used for laminating a constituent member of a flexible image display device.
   [xix] A laminated sheet, comprising a member sheet having a tensile strength at 25° C. measured in according with ASTM D882 of 10 to 900 MPa on at least one surface of the adhesive sheet according to any one of [i] to [xviii].
   [xx] A laminated sheet, comprising the adhesive sheet according to any one of [i] to [xviii] on at least one surface of a member sheet having a tensile strength at 25° C. measured in according with ASTM D882 of 10 to 900 MPa.
   [xxi] The laminated sheet according to [xix] or [xx], wherein the member sheet is: a resin sheet containing at least one resin selected from the group consisting of a polyester resin, a cycloolefin resin, a triacetylcellulose resin, a polymethyl methacrylate resin, an epoxy resin, a polyimide resin, an aramid resin, and a polyurethane resin as a main component; or glass.
   [xxii] A flexible image display device, comprising the laminated sheet according to any one of [xix] to [xxi].

### Effects of the Disclosure

The adhesive sheet according to an embodiment of the present disclosure is the adhesive sheet formed from the adhesive composition containing the specific long-chain linear or branched alkyl group and the hydroxy group-containing acrylic polymer. The adhesive sheet has a remarkably low storage elastic modulus at low temperature, and therefore can yield excellent flexibility at low temperature and excellent recovering ability. Specifically, the adhesive sheet can be suitably used as an adhesive sheet used for a flexible image display device.

### EMBODIMENTS OF THE DISCLOSURE

Hereinafter, the embodiment of the present disclosure will be described in detail.

In the embodiment of the present disclosure, the term “film” is intended to encompass sheets, and the term “sheet” is intended to encompass films.

The term “panel” as used in “image display panel” and “protection panel” is intended to encompass plates, sheets, and films.

In the embodiment of the present disclosure, “X to Y,” wherein X and Y are given numbers, is intended to encompass “preferably greater than X” and “preferably less than Y” unless otherwise specified, in addition to a meaning of “not less than X and not greater than Y.”

The expression “not less than X,” wherein X is a given number, is intended to encompass “preferably greater than X” unless otherwise specified. The expression “not greater than Y,” wherein Y is a given number, is intended to encompass “preferably less than Y” unless otherwise specified.

Further, the expression “X and/or Y,” wherein X and Y are each a given form, is intended to mean at least one of X and Y, and to include the following three meanings: only X; only Y; and X and Y.

In the embodiment of the present disclosure, “main component” means a component significantly affects properties of an object, and a content of the component is typically not less than 30 wt. %, preferably not less than 35 wt. %, and more preferably not less than 50 wt. % in the object. The main component is often a component with the highest weight proportion in the object, and cases where the proportion is not less than 50 wt. %, specifically not less than 55 wt. %, specifically not less than 60 wt. %, specifically not less than 70 wt. %, specifically not less than 80 wt. %, and specifically not less than 90 wt. % (including 100 wt. %) are assumed.

In the embodiment of the present disclosure, the term “(meth)acryl” means to encompass “acryl” and “methacryl”, the term “(meth)acrylate” means to encompass “acrylate” and “methacrylate”, and the term “(meth)acryloyl” means to encompass “acryloyl” and “methacryloyl”.

The term “acrylic polymer” means to encompass a polymer having a monomer unit derived from a (meth)acrylate, and means to encompass a (meth)acrylic copolymer.

<<The Present Adhesive Sheet>>

The adhesive sheet according to an example of the embodiment of the present disclosure (also referred to as “the present adhesive sheet”) is an adhesive sheet formed from an adhesive composition [I] containing an acrylic polymer (A), and specifically useful as an adhesive sheet used for laminating a constituent member of a flexible image display device.

<<Adhesive Composition [I]>>

The adhesive composition [I] contains the acrylic polymer (A), and preferably contains the acrylic polymer (A) as a main component.

<Acrylic Polymer (A)>

The acrylic polymer (A) used in the embodiment of the present disclosure is an acrylic polymer having: a structural portion derived from a linear or branched (meth)acrylate (a1) whose alkyl group has 5 to 20 carbon atoms, represented by the following (Formula 1); and a structural portion derived from a hydroxy group-containing (meth)acrylate (a2). The acrylic polymer (A) is preferably obtained by copolymerizing a mixture containing the (a1) and the hydroxy group-containing (meth)acrylate (a2) as copolymerization components to constitute the acrylic polymer (A). The acrylic polymer (A) may also be obtained by copolymerizing a monomer component (a3) other than the (a1) and the hydroxy group-containing (meth)acrylate (a2) therewith as the copolymerization components.

The acrylic polymer (A) used in the embodiment of the present disclosure contains the linear or branched alkyl (meth)acrylate (a1) whose alkyl group has 5 to 20 carbon atoms, represented by the following (Formula 1), as the copolymerization component,

CH₂═CH(R₁)—COO(R₂) (Formula 1)
wherein R₁ represents a hydrogen atom or a methyl group, and R₂ represents a linear or branched alkyl group having 5 to 20 carbon atoms.

<Linear or Branched Alkyl (Meth)Acrylate (a1) Whose Alkyl Group has 5 to 20 Carbon Atoms>

Examples of the linear alkyl (meth)acrylate (a1) whose alkyl group has 5 to 20 carbon atoms, represented by Formula 1, include linear alkyl (meth)acrylates such as n-pentyl (meth)acrylate, n-hexyl (meth)acrylate, n-heptyl (meth)acrylate, n-octyl (meth)acrylate, n-nonyl (meth)acrylate, n-decyl (meth)acrylate, n-lauryl (meth)acrylate, n-tridecyl (meth)acrylate, and n-stearyl (meth)acrylate. These may be used alone, or two or more of these may be used in combination.

Examples of the branched alkyl (meth)acrylate whose alkyl group has 5 to 20 carbon atoms, represented by Formula 1, include branched alkyl (meth)acrylates such as isopentyl (meth)acrylate, neopentyl (meth)acrylate, 2-ethylhexyl (meth)acrylate, isooctyl (meth)acrylate, isononyl (meth)acrylate, isodecyl (meth)acrylate, and isostearyl (meth)acrylate. These may be used alone, or two or more of these may be used in combination. These may be used in combination with the linear alkyl (meth)acrylate.

Among these, the branched alkyl (meth)acrylate is preferably used from the viewpoint that hydrogen abstraction easily occurs in a high-energy state such as high temperature and ultraviolet radiation to consequently form a crosslinked structure efficiently. Among these, preferred is a branched alkyl (meth)acrylate whose alkyl group has 6 to 18, further 6 to 16, particularly 8 to 12, and more particularly 8 to 10 carbon atoms.

Among these, the linear alkyl (meth)acrylate is preferable in terms of adhesiveness and recovering ability, specifically reduction in the storage shearing elastic modulus (G′) at low temperature to improve bendability. Among these, a linear alkyl (meth)acrylate whose alkyl group has 6 to 18, further 6 to 16, particularly 8 to 12, more particularly 8 to 10 carbon atoms is preferable, and examples thereof include n-pentyl (meth)acrylate, n-hexyl (meth)acrylate, n-octyl (meth)acrylate, n-nonyl (meth)acrylate, and n-decyl (meth)acrylate. Among these, n-octyl (meth)acrylate, n-nonyl (meth)acrylate, and n-decyl (meth)acrylate are preferable, and n-octyl (meth)acrylate is particularly preferable.

In recent years, use of a plant-derived raw material being a renewable resource has been recommended as a part of measures for exhaustion of fossil resources, global warming, etc. Required is an adhesive with a high biomass degree, which uses the global environment-friendly plant-derived raw material.

Therefore, a plant-derived component is preferably used as a copolymerization component to constitute the acrylic polymer (A) in order to increase the biomass degree of the adhesive sheet.

Examples of plant-derived (meth)acrylates include n-octyl (meth)acrylate, n-lauryl (meth)acrylate, n-stearyl acrylate, isostearyl acrylate, isobornyl acrylate, and tetrahydrofurfuryl acrylate.

Among these, n-octyl (meth)acrylate is particularly preferable because of excellent compatibility with other copolymerization components, excellent adhesive properties when formed into the acrylic polymer (A), excellent flexibility, and excellent compatibility with other components constituting the adhesive composition.

The biomass degree of the present adhesive sheet is preferably not less than 40%, further preferably not less than 45%, and particularly preferably not less than 50%. The upper limit is 100%. A higher biomass degree can better contribute to reduction in environmental load.

Here, the biomass degree of the present adhesive sheet is a weight proportion of a portion where plant-derived raw materials used for manufacturing the adhesive sheet are incorporated relative to a total weight of the adhesive sheet. The biomass degree of the present adhesive sheet can be measured in accordance with a test standard for a bio-base concentration, ASTM D6866-21, by using a 14C-AMS dedicated device based on a tandem accelerator.

When a biomass degree of each component constituting the adhesive composition [I] is known, the biomass degree of the present adhesive sheet can be calculated by summing up products of the biomass degree of each component constituting the adhesive composition [I] and its weight proportion.

The biomass degree of the present adhesive sheet may be the value obtained by any of the above methods within the above range.

The biomass degree of the acrylic polymer (A) can be determined with the following calculation formula.

Biomass degree (%) of acrylic polymer (A)=[(Biomass degree of plant-derived monomer in acrylic polymer (A))×(Weight of plant-derived monomer in acrylic polymer (A))/(Weight of all constituent monomers in acrylic polymer (A))]×100

From the viewpoint of further reduction in the storage shearing elastic modulus (G′) at low temperature to improve bendability, acrylates are particularly preferable.

In the embodiment of the present disclosure, a content of the alkyl (meth)acrylate (a1) represented by (Formula 1) is preferably 50 to 95 wt. % relative to an entirety of the copolymerization components constituting the acrylic polymer (A) in terms of reduction in the storage shearing elastic modulus (G′) at low temperature, and more preferably 60 to 90 wt. %, and particularly preferably 70 to 85 wt. %. The proportion of the alkyl (meth)acrylate (a1) of not less than the above lower limit is preferable because the storage shearing elastic modulus (G′) at low temperature can be reduced, and the proportion of not greater than the upper limit is preferable because other physical properties such as adhesiveness can be achieved at the same time.

<Hydroxy Group-Containing (Meth)acrylate (a2)>

The acrylic polymer (A) used in the embodiment of the present disclosure contains the hydroxy group-containing (meth)acrylate (a2) in addition to the component (a1) as the copolymerization component.

Containing the hydroxy group-containing (meth)acrylate (a2) can keep cohesiveness and adhesiveness to the adherend even with the adhesive sheet having a significantly low storage elastic modulus, and can yield the adhesive sheet having excellent recovering ability.

Examples of the hydroxy group-containing (meth)acrylate (a2) include: hydroxyalkyl (meth)acrylates, such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates, such as caprolactone-modified 2-hydroxyethyl (meth)acrylate; oxyalkylene-modified (meth)acrylates, such as diethylene glycol (meth)acrylate and polyethylene glycol (meth)acrylate; primary hydroxy group-containing (meth)acrylates, such as 2-acryloyloxyethyl-2-hydroxyethylphthalic acid; secondary hydroxy group-containing (meth)acrylates, such as 2-hydroxypropyl (meth)acrylate, 2-hydroxybutyl (meth)acrylate, and 3-chloro-2-hydroxypropyl (meth)acrylate; and tertiary hydroxy group-containing (meth)acrylates, such as 2,2-dimethyl-2-hydroxyethyl (meth)acrylate. These may be used alone, or two or more of these may be used in combination.

Among the hydroxy group-containing (meth)acrylates (a2), hydroxy group-containing (meth)acrylates having a hydroxyalkyl group having 1 to 10, further 1 to 6, particularly 2 to 4 carbon atoms, such as for example, 2-hydroxyethyl (meth)acrylate, 2-hydroxypropyl (meth)acrylate, and 4-hydroxybutyl (meth)acrylate, are preferable. In terms of reduction in the storage shearing elastic modulus (G′) at low temperature, the primary hydroxy group-containing (meth)acrylates such as, for example, 2-hydroxyethyl (meth)acrylate and 4-hydroxybutyl (meth)acrylate are preferable, and 4-hydroxybutyl (meth)acrylate is particularly preferable.

A content of the hydroxy group-containing (meth)acrylate (a2) is preferably 5 to 50 wt. %, more preferably 10 to 40 wt. %, and particularly preferably 15 to 30 wt. % relative to an entirety of the copolymerization components of the acrylic polymer (A) in terms of adhesiveness. The content of this hydroxy group-containing (meth)acrylate (a2) of not less than the lower limit is preferable because high adhesiveness can be obtained, and the content thereof of not greater than the upper limit is preferable because an increase in the storage shearing elastic modulus (G′) at low temperature can be inhibited.

The specifically excellent performance for repeated bending actions while reducing the storage shearing elastic modulus (G′) at low temperature to improve flexibility can be obtained by the hydroxy group-containing (meth)acrylate (a2), which is a hydrophilic component. The cohesiveness to reduce buckling, the recovering ability, and the adhesiveness to the adherend result from a hydrogen bond, which is derived from the hydroxy group, formed inside the adhesive sheet and/or between the adhesive sheet and the adherend. Meanwhile, if the hydroxy group-containing (meth)acrylate (a2), which is hydrophilic, and the alkyl (meth)acrylate (a1), which is hydrophobic, exhibit insufficient compatibility, a phase-separated structure may be generated to cause a defect of the polymer to be cloud. However, use of the hydroxy group-containing (meth)acrylate (a2) within the predetermined range can yield an optically-uniform, transparent adhesive sheet with good folding resistance.

In the embodiment of the present disclosure, a monomer component (a3) (except for the components (a1) and (a2)) copolymerizable with the alkyl (meth)acrylate (a1) represented by (Formula 1) and/or the hydroxy group-containing (meth)acrylate (a2) can be used in combination. Examples of such a monomer component (a3) include ethylenically unsaturated group monomers having a functional group other than a hydroxy group, alkyl (meth)acrylates other than the (a1), and other copolymerizable monomers. These may be used alone, or two or more of these may be used in combination.

Examples of the ethylenically unsaturated group monomer having a functional group other than a hydroxy group (hereinafter may be referred to as “functional group-containing ethylenically unsaturated monomer”) include a functional group-containing monomer having a nitrogen atom, a carboxy group-containing monomer, an acetoacetyl group-containing monomer, and a glycidyl group-containing monomer.

Among these, the functional group-containing ethylenically unsaturated monomer is preferably the functional group-containing monomer having a nitrogen atom, more preferably an amino group-containing monomer, an amide group-containing monomer, and an isocyanate group-containing monomer, and further preferably an amino group-containing monomer in terms of imparting the cohesiveness and a crosslinking-accelerating effect.

Examples of the amino group-containing monomer as the functional group-containing monomer having a nitrogen atom include: primary amino group-containing (meth)acrylates, such as aminomethyl (meth)acrylate and aminoethyl (meth)acrylate; secondary amino group-containing (meth)acrylates, such as t-butylaminoethyl (meth)acrylate and t-butylaminopropyl (meth)acrylate; and tertiary amino group-containing (meth)acrylates, such as ethylaminoethyl (meth)acrylate, dimethylaminoethyl (meth)acrylate, diethylaminoethyl (meth)acrylate, dimethylaminopropyl (meth)acrylate, diethylaminopropyl (meth)acrylate, and dimethylaminopropylacrylamide.

Examples of the amide group-containing monomer include: (meth)acrylamide; N-alkyl (meth)acrylamides, such as N-methyl(meth)acrylamide, N-ethyl(meth)acrylamide, N-propyl(meth)acrylamide, N-n-butyl(meth)acrylamide, diacetone(meth)acrylamide, and N,N′-methylenebis(meth)acrylamide; N,N-dialkyl(meth)acrylamides, such as N,N-dimethyl(meth)acrylamide, N,N-diethyl(meth)acrylamide, N,N-dipropyl(meth)acrylamide, N,N-ethylmethylacrylamide, and N,N-diallyl(meth)acrylamide; hydroxyalkyl(meth)acrylamides, such as N-hydroxymethyl(meth)acrylamide and N-hydroxyethyl(meth)acrylamide; and alkoxyalkyl(meth)acrylamides, such as N-methoxymethyl(meth)acrylamide and N-(n-butoxymethyl)(meth)acrylamide.

Examples of the isocyanate group-containing monomer include 2-(meth)acryloyloxyethyl isocyanate and an alkylene oxide adduct thereof. The isocyanate group may be protected with a blocking agent such as methyl ethyl ketone oxime, 3,5-dimethylpyrazole, 1,2,4-triazole, and diethyl malonate.

Examples of the carboxy group-containing monomer include (meth)acrylic acid, carboxyethyl (meth)acrylate, 2-(meth)acryloyloxyethylhexahydrophthalic acid, 2-(meth)acryloyloxypropylhexahydrophthalic acid, 2-(meth)acryloyloxyethylphthalic acid, 2-(meth)acryloyloxypropylphthalic acid, 2-(meth)acryloyloxyethylmaleic acid, 2-(meth)acryloyloxypropylmaleic acid, 2-(meth)acryloyloxyethylsuccinic acid, 2-(meth)acryloyloxypropylsuccinic acid, crotonic acid, fumaric acid, maleic acid, itaconic acid, monomethyl maleate, and monomethyl itaconate.

Examples of the acetoacetyl group-containing monomer include 2-(acetoacetoxy)ethyl (meth)acrylate and allyl acetoacetate.

Examples of the glycidyl group-containing monomer include glycidyl (meth)acrylate and allylglycidyl (meth)acrylate.

These functional group-containing ethylenically unsaturated monomers may be used alone, or two or more of these may be used in combination.

An upper limit of a content of the functional group-containing ethylenically unsaturated monomer is preferably not greater than 30 wt. %, more preferably not greater than 20 wt. %, further preferably not greater than 10 wt. %, and particularly preferably not greater than 5 wt. % relative to the entirety of the copolymerization components of the acrylic polymer (A) from the viewpoint of reduction in decrease in adhesiveness due to bleed out. A lower limit thereof is typically 0 wt. %.

Examples of the alkyl (meth)acrylate other than the (a1) include: alkyl (meth)acrylates having an alkyl group having 1 to 4, or more than 20 carbon atoms, such as linear alkyl (meth)acrylates such as methyl (meth)acrylate, ethyl (meth)acrylate, n-propyl (meth)acrylate, isopropyl (meth)acrylate, n-butyl (meth)acrylate, icosyl (meth)acrylate, and behenyl (meth)acrylate, and branched alky (meth)acrylates such as isopropyl (meth)acrylate, isobutyl (meth)acrylate, sec-butyl (meth)acrylate, t-butyl (meth)acrylate, and isoicosyl (meth)acrylate; and alicyclic (meth)acrylates, such as cyclohexyl (meth)acrylate, t-butylcyclohexyl (meth)acrylate, isobornyl (meth)acrylate, 3,3,5-trimethylcyclohexyl (meth)acrylate, and adamantyl (meth)acrylate. These may be used alone, or two or more of these may be used in combination.

When the alkyl (meth)acrylate other than the (a1) is contained, an upper limit of a content thereof is preferably not greater than 20 wt. %, more preferably not greater than 10 wt. %, and further preferably not greater than 5 wt. % relative to the entirety of the copolymerization components of the acrylic polymer (A) from the viewpoint of keeping the recovering ability. The lower limit is typically 0 wt. %.

Examples of the other copolymerizable monomer include: aromatic (meth)acrylates, such as phenyl (meth)acrylate, benzyl (meth)acrylate, phenoxyethyl (meth)acrylate, phenyl diethylene glycol (meth)acrylate, phenoxy polyethylene glycol (meth)acrylate, phenoxy polyethylene glycol-polypropylene glycol (meth)acrylate, nonylphenol ethylene oxide-adduct (meth)acrylate; (meth)acrylates having a benzophenone structure, such as 4-acryloyloxybenzophenone, 4-acryloyloxyethoxybenzophenone, 4-acryloyloxy-4′-methoxybenzophenone, 4-acryloyloxyethoxy-4′-methoxybenzophenone, 4-acryloyloxy-4′-bromobenzophenone, 4-acryloyloxyethoxy-4′-bromobenzophenone, 4-methacryloyloxybenzophenone, 4-methacryloyloxyethoxybenzophenone, 4-methacryloyloxy-4′-methoxybenzophenone, 4-methacryloyloxyethoxy-4′-methoxybenzophenone, 4-methacryloyloxy-4′-bromobenzophenone, 4-methacryloyloxyethoxy-4′-bromobenzophenone, and a mixture thereof; heteroring-containing (meth)acrylates, such as (meth)acryloylmorpholine and tetrahydrofurfuryl (meth)acrylate; and vinyl monomers, such as acrylonitrile, methacrylonitrile, styrene, α-methylstyrene, vinyl stearate, vinyl propionate, vinyl acetate, vinyl chloride, vinylidene chloride, alkyl vinyl ether, vinyltoluene, vinylpyridine, vinylpyrrolidone, itaconic acid dialkyl ester, fumaric acid dialkyl ester, allyl alcohol, acryl chloride, methyl vinyl ketone, N-acrylamidomethyltrmethylammonium chloride, allyltrimethylammonium chloride, and dimethylallyl vinyl ketone. A monofunctional (meth)acrylate (B), described later, may be used as the copolymerization component. These may be used alone, or two or more of these may be used in combination.

In the acrylic polymer (A), a photoactive portion, for example a polymerizable carbon-carbon double bond group, may be introduced on a side chain. This photoactive portion can enhance crosslinking efficiency of the adhesive composition [I] and crosslink the adhesive composition [I] in a shorter time, which can improve the productivity.

Examples of a method for introducing the polymerizable carbon-carbon double bond group on the side chain of the acrylic polymer (A) include a method including: producing a copolymer having the aforementioned hydroxy group-containing (meth)acrylate (a2) and functional group-containing ethylenically unsaturated monomer; and then subjecting a compound having a functional group that can react with these functional groups and the polymerizable carbon-carbon double bond group to condensation or an addition reaction while keeping the activity of the polymerizable carbon-carbon double bond group.

Examples of combinations of these functional groups include an epoxy group (glycidyl group) and a carboxy group, an amino group and a carboxy group, an amino group and an isocyanate group, an epoxy group (glycidyl group) and an amino group, a hydroxy group and an epoxy group, and a hydroxy group and an isocyanate group. Among these combinations of the functional groups, the combination of a hydroxy group and an isocyanate group is preferable in terms of ease of reaction control. Specifically, preferable is a combination in which the copolymer has a hydroxy group and the compound has an isocyanate group.

Examples of the isocyanate compound having the polymerizable carbon-carbon double bond group include the aforementioned 2-(meth)acryloyloxyethyl isocyanate and alkylene oxide adducts thereof.

A content of the compound having the functional group that can react with the functional group and the polymerizable carbon-carbon double bond group is preferably not greater than 10 parts by weight, more preferably not greater than 5 parts by weight, further preferably not greater than 1 part by weight, and particularly preferably not greater than 0.1 part by weight relative to 100 parts by weight of the acrylic polymer (A) from the viewpoint of improvement of the adhesiveness and stress-relaxing ability. The lower limit is typically 0 parts by weight.

A glass transition temperature (Tg) of the acrylic polymer (A) is preferably not higher than −20° C., more preferably not higher than −23° C., further preferably not higher than −25° C., and particularly preferably not higher than −30° C. in terms of reduction in the storage shearing elastic modulus (G′) at low temperature. With considering glue ooze, etc., a lower limit of the glass transition temperature (Tg) is typically −50° C.

In the embodiment of the present disclosure, the glass transition temperature (Tg) of the acrylic polymer (A) can be determined by using a dynamic viscoelasticity measuring apparatus and reading a temperature at which a loss tangent (loss shearing elastic modulus G″/Storage shearing elastic modulus G′=tan δ) when the dynamic viscoelasticity measured with a shearing mode at a frequency of 1 Hz becomes maximum.

For example, the acrylic polymer (A) is molded into a cylinder with 8 mm in diameter (height: 1.0 mm), and a loss tangent (tan δ) of this cylinder can be measured by using a viscoelasticity measuring apparatus (trade name: “DHR 2” available from T.A. Instruments) under the following measurement conditions.

(Measurement Conditions)
Measurement tool: Φ 8 mm parallel plate
Strain: 0.1%
Frequency: 1 Hz
Measurement temperature: −60 to 100° C.
Temperature raising rate: 5° C./min

A weight average molecular weight (Mw) of the acrylic polymer (A) is preferably not less than 600,000, more preferably not less than 700,000, and further preferably not less than 800,000 from the viewpoint of obtaining the adhesive composition [I] with high cohesiveness.

An upper limit of the weight average molecular weight (Mw) of the acrylic polymer (A) is preferably not greater than 1,500,000, more preferably not greater than 1,200,000, further preferably not greater than 1,100,000, and still further preferably 1,000,000 in terms of operability and stirring uniformity.

In the embodiment of the present disclosure, the weight average molecular weight (Mw) can be determined as follows, for example.

### (Method for Measuring Weight Average Molecular Weight)

A measurement sample is prepared by dissolving 4 mg of the acrylic polymer (A) in 12 mL of tetrahydrofuran (THF), and a molecular weight distribution curve is measured under the following conditions with the use of a gel permeation chromatography (GPC) analyzer (HLC-8320 GPC available from Tosoh Co. Ltd.) to determine the weight average molecular weight (Mw).
Guard column: TSK guard column HXL
Separation column: TSK gel GMHXL (4 columns)
Temperature: 40° C.
Injection amount: 100 μL
In terms of polystyrene standard
Solvent: THF
Flow rate: 1.0 mL/minute

<Monofunctional (Meth)acrylate (B)>

In the embodiment of the present disclosure, the adhesive composition [I] preferably contains a monofunctional (meth)acrylate (B) in addition to the acrylic polymer (A) in terms of further reduction in the storage elastic modulus at low temperature while keeping sufficient recovering ability.

The monofunctional (meth)acrylate (B) is a (meth)acrylate having one (meth)acryloyl group, and specifically, preferably a (meth)acrylate (bi) having a glycol skeleton in terms of reduction in the storage elastic modulus at low temperature.

Examples of the glycol skeleton include an ethylene glycol skeleton, a propylene glycol skeleton, a diethylene glycol skeleton, a butanediol skeleton, a hexanediol skeleton, a 1,4-cyclohexanedimethanol skeleton, a glycolic acid skeleton, and a polyglycol skeleton. Among these, a polyethylene glycol skeleton and/or a polypropylene glycol skeleton is more preferable.

The monofunctional (meth)acrylate (B) is preferably a urethane (meth)acrylate having at least one urethane bond, in terms of improvement of toughness and adhesiveness to the adherend.

The monofunctional (meth)acrylate (B) has a weight average molecular weight (Mw) of preferably not less than 5,000, particularly preferably not less than 7,000, and further preferably not less than 9,000 in terms of prevention of bleed out. Meanwhile, the weight average molecular weight (Mw) is preferably not greater than 100,000, particularly preferably not greater than 50,000, and further preferably not greater than 30,000 in terms of operability and stirring uniformity.

A content of the monofunctional (meth)acrylate (B) is preferably 0.1 to 45 parts by weight, more preferably 1 to 35 parts by weight, particularly preferably 2 to 30 parts by weight, and further preferably 3 to 25 parts by weight relative to 100 parts by weight of the acrylic polymer (A).

Such a content can reduce the storage elastic modulus at low temperature while keeping sufficient recovering ability.

<Radical-Polymerizable Compound>

The adhesive composition [I] preferably contains a radical-polymerizable compound other than the monofunctional (meth)acrylate (B) in addition to the acrylic polymer (A) from the viewpoint of improvement of the productivity with an increase in a line speed. This radical-polymerizable compound allows the adhesive composition [I] to quickly form the crosslinked structure with the same irradiation dose of ultraviolet radiation, for example, which can impart the cohesiveness and high recovering ability in bending to the adhesive layer (adhesive sheet). The adhesive layer having appropriate cohesiveness can prevent glue ooze in the case of winding into a roll and keep the good adhesiveness. The high recovering ability in bending can improve a folding trace and prevent delamination in the bending portion.

Examples of the radical-polymerizable compound include (meth)acrylic monomers and (meth)acrylic oligomers having two or more functional groups. These may be used alone, or two or more of these may be used in combination.

Examples of the (meth)acrylic monomer having two or more functional groups include pentanediol di(meth)acrylate, hexanediol di(meth)acrylate, heptanediol di(meth)acrylate, octanediol di(meth)acrylate, nonanediol di(meth)acrylate, decanediol di(meth)acrylate, undecanediol di(meth)acrylate, dodecanediol di(meth)acrylate, 1,4-butanediol di(meth)acrylate, glycerol di(meth)acrylate, neopentyl glycol di(meth)acrylate, glycerol glycidyl ether di(meth)acrylate, tricyclodecane dimethacrylate, tricyclodecanedimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, neopentyl glycol di(meth)acrylate, trimethylolpropanetrioxyethyl (meth)acrylate, ε-caprolactone-modified tris(2-hydroxyethyl) isocyanurate tri(meth)acrylate, pentaerythritol tri(meth)acrylate, propoxylated pentaerythritol tri(meth)acrylate, ethoxylated pentaerythritol tri(meth)acrylate, pentaerythritol tetra(meth)acrylate, propoxylated pentaerythritol tetra(meth)acrylate, ethoxylated pentaerythritol tetra(meth)acrylate, dipentaerythritol hexa(meth)acrylate, polyethylene glycol di(meth)acrylate, polypropylene glycol di(meth)acrylate, polytetramethylene glycol di(meth)acrylate, tris(acryloxyethyl) isocyanurate, dipentaerythritol hexa(meth)acrylate, dipentaerythritol penta(meth)acrylate, tripentaerythritol hexa(meth)acrylate, tripentaerythritol penta(meth)acrylate, neopentyl glycol hydroxypivalate di(meth)acrylate, di(meth)acrylate of ε-caprolactone adduct of neopentyl glycol hydroxypivalate, trimethylolpropane tri(meth)acrylate, trimethylolpropane polyethoxy tri(meth)acrylate, and ditrimethylolpropane tetra(meth)acrylate.

Examples of the (meth)acrylic oligomer having two or more functional groups include polyfunctional (meth)acrylate oligomers, such as polyester (meth)acrylate oligomers, epoxy (meth)acrylate oligomers, urethane (meth)acrylate oligomers, and polyether (meth)acrylate oligomers.

Among these, urethane (meth)acrylate oligomers are preferable from the viewpoint of imparting appropriate toughness to the cured product.

A content of the radical-polymerizable compound is preferably not less than 0.1 part by weight, more preferably not less than 0.5 parts by weight, and further preferably not less than 1 part by weight relative to 100 parts by weight of the acrylic polymer (A) from the viewpoints of shape stability of the adhesive sheet and imparting durability to the laminated sheet. The upper limit is preferably not greater than 10 parts by weight, more preferably not greater than 7 parts by weight, particularly preferably not greater than 5 parts by weight, and further preferably not greater than 3 parts by weight in terms of reduction in the storage shearing elastic modulus (G′) at low temperature.

In addition to the radical-polymerizable compound, a thermal crosslinker can be used in combination in terms of further improvement of the crosslinking density to improve long-term reliability.

Examples of such a thermal crosslinker include an isocyanate crosslinker, an epoxy crosslinker, an aziridine crosslinker, a melamine crosslinker, an aldehyde crosslinker, an amine crosslinker, and a metal chelate crosslinker. Among these, an isocyanate crosslinker is preferably used in terms of excellent reactivity with the acrylic polymer (A).

<Photopolymerization Initiator (C)>

In the embodiment of the present disclosure, a photopolymerization initiator (C) is preferably further contained in addition to the acrylic polymer (A) and preferably the (B). The photopolymerization initiator (C) may be a compound that generates radicals with active energy radiation.

The photopolymerization initiator (C) is largely classified into two types with its radical generation mechanism: a cleavage-type photopolymerization initiator in which a single bond in the initiator itself can be cleaved and decomposed to generate radicals; and a hydrogen abstraction-type photopolymerization initiator in which an excited initiator and a hydrogen donner in the system can form an exciplex to transfer hydrogen in the hydrogen donner.

The photopolymerization initiator (C) may be any of the cleavage-type photopolymerization initiator and the hydrogen abstraction-type photopolymerization initiator, each of them may be used singly or may be mixed for use, and one or more of them may be used in combination.

In the embodiment of the present disclosure, the hydrogen abstraction-type photopolymerization initiator is preferably used in terms of efficient crosslinking without requiring a functional group such as a polymerizable carbon-carbon double bond group in the acrylic polymer (A) itself.

Examples of the cleavage-type photopolymerization initiator include 2,2-dimethoxy-1,2-diphenylethan-1-one, 1-hydroxycyclohexyl phenyl ketone, 2-hydroxy-2-methyl-1-phenylpropan-1-one, 1-(4-(2-hydroxyethoxy)phenyl)-2-hydroxy-2-methyl-1-propan-1-one, 2-hydroxy-1-[4-{4-(2-hydroxy-2-methyl-propionyl)benzyl}phenyl]-2-methylpropan-1-one, oligo(2-hydroxy-2-methyl-1-(4-(methylvinyl)phenyl)propanone), methyl phenylglyoxylate, 2-benzyl-2-dimethylamino-1-(4-morpholinophenyl)butan-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, bis(2,6-dimethoxybenzoyl)-2,4,4-trimethylpentylphosphine oxide, and derivatives thereof.

Examples of the hydrogen abstraction-type photopolymerization initiator include benzophenone, 4-methylbenzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, methyl benzoylformate, bis(2-phenyl-2-oxoacetate)oxybisethylene, 4-(1,3-acryloyl-1,4,7,10,13-pentaoxotridecyl)benzophenone, thioxanthone, 2-chlorothioxanthone, 3-methylthioxanthone, 2,4-dimethylthioxanthone, 2-methylanthraquinone, 2-ethylanthraquinone, 2-t-butylanthraquinone, 2-aminoanthraquinone, and derivatives thereof. Among these, 4-methylbenzophenone and 2,4,6-trimethylbenzophenone are preferable.

A content of the photopolymerization initiator (C) is preferably typically 0.1 to 10 parts by weight, specifically 0.5 to 5 parts by weight, and more specifically 1 to 3 parts by weight relative to 100 parts by weight of the acrylic polymer (A). The content of not less than the above lower limit tends to prevent curing failure, and the content of not greater than the above upper limit tends to easily inhibit a decrease in solution stability, such as precipitation from the adhesive composition [I], to inhibit problems of embrittiement and coloring.

<Other Components>

The adhesive component [I] can appropriately contain various additives as “other components” within a range not impairing the effect of the embodiment of the present disclosure. Examples of the other components include a silane-coupling agent, a UV absorber, an antirust agent, a tackifier resin, an antioxidant, a light stabilizer, a metal deactivator, an antiaging agent, a moisture absorber and inorganic particles.

As necessary, reaction catalysts such as a tertiary amine compound, a quaternary ammonium compound, and a tin laurate compound may be appropriately contained.

These may be used alone, or two or more of these may be used in combination.

(Silane-Coupling Agent)

The silane-coupling agent is an organic silicon compound having not less than one reactive functional group and not less than one alkoxy group bonded to a silicon atom in the structure. Examples of the reactive functional group include an epoxy group, a (meth)acryloyl group, a mercapto group, a hydroxy group, a carboxy group, an amino group, an amide group, and an isocyanate group. Among these, an epoxy group and a mercapto group are preferable in terms of balance of durability.

As the alkoxy group bonded to a silicon atom, an alkoxy group having 1 to 8 carbon atoms is preferably contained in terms of durability and storage stability, and a methoxy group and an ethoxy group are particularly preferable. The silane-coupling agent may have an organic substituent other than the reactive functional group and the alkoxy group bonded to a silicon atom, such as, for example, an alkyl group and a phenyl group.

Examples of the silane-coupling agent used in the embodiment of the present disclosure include: monomer-type epoxy group-containing silane coupling agents being silane compounds such as 3-glycidoxypropyltrimethoxysilane, 3-glycidoxypropyltriethoxysilane, 3-glycidoxypropylmethyldiethoxysilane, 3-glycidoxypropylmethyldimethoxysilane, and 2-(3,4-epoxycyclohexyl)ethyltimethoxysilane; oligomer-type epoxy group-containing silane-coupling agents being silane compounds in which a part of the above silane compound is hydrolytically condensing-polymerized or in which the above silane compound and an alkyl group-containing silane compound, such as methyltrethoxysilane, ethyltriethoxysilane, methyltrimethoxysilane, and ethyltrimethoxysilane, are co-condensed; monomer-type mercapto group-containing silane coupling agents being silane compounds such as 3-mercaptopropyltrimethoxysilane, 3-mercaptopropyltriethoxysilane, γ-mercaptopropyldimethoxymethylsilane, and 3-mercaptopropylmethyldimethoxysilane; oligomer-type mercapto group-containing silane-coupling agents being silane compounds in which a part of the above silane compound is hydrolytically condensing-polymerized or in which the above silane compound and an alkyl group-containing silane compound, such as methyltriethoxysilane, ethyltriethoxysilane, methyltrimethoxysilane, and ethyltrimethoxysilane, are co-condensed; (meth)acryloyl group-containing silane-coupling agents, such as 3-acryloxypropyltrimethoxysilane, 3-methacryloxypropyltimethoxysilane, 3-methacryloxypropylmethyldiethoxysilane and 3-methacryloxypropyltriethoxysilane; amino group-containing silane-coupling agents, such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, and N-phenyl-3-aminopropyltrimethoxysilane; isocyanate group-containing silane coupling agents, such as 3-isocyanatepropyltrethoxysilane; and vinyl group-containing silane-coupling agents, such as vinyltrimethoxysilane and vinyltriethoxysilane.

These may be used alone, or two or more of these may be used in combination.

Among these, the epoxy group-containing silane-coupling agent and the mercapto group-containing silane coupling agent are preferably used, and specifically, the epoxy group-containing silane-coupling agent is preferable in terms of excellent durability.

A content of the silane-coupling agent is preferably 0.005 to 10 parts by weight, particularly preferably 0.01 to 5 parts by weight, and further preferably 0.05 to 1 part by weight relative to 100 parts by weight of the acrylic polymer (A). The content of not less than the above lower limit tends to improve durability, and the content of not greater than the above upper limit tends to improve durability.

(UV Absorber)

Examples of the UV absorber include benzophenone-based UV absorbers, benzotriazole-based UV absorbers, triazine-based UV absorbers, salicylic acid-based UV absorbers, cyanoacrylate-based UV absorbers, and benzoxazine-based UV absorbers. These UV absorbers may be used alone, or two or more of these may be used in combination.

A content of the UV absorber is preferably 0.01 to 20 parts by weight, particularly preferably 0.1 to 15 parts by weight, and further preferably 0.5 to 10 parts by weight relative to 100 parts by weight of the acrylic polymer (A). The content of not less than the above lower limit tends to improve light-resistant reliability, and the content of not greater than the above upper limit tends to improve yellowing resistance.

(Antirust Agent)

The antirust agent is preferably triazoles and benzotriazoles, for example. The antirust agent can prevent corrosion of an optical member.

A content of the antirust agent is preferably 0.01 to 5 parts by weight, and specifically preferably not less than 0.1 part by weight and not greater than 3 parts by weight relative to 100 parts by weight of the acrylic polymer (A).

A content of the other components is preferably not greater than 5 parts by weight, particularly preferably not greater than 1 part by weight, and further preferably not greater than 0.5 parts by weight relative to 100 parts by weight of the acrylic polymer (A), and the lower limit is typically 0 parts by weight. An excessively large content thereof tends to decrease compatibility with the acrylic polymer (A) to deteriorate durability.

The adhesive composition [I] is prepared by mixing predetermined amounts of the acrylic polymer (A), preferably additionally the monofunctional (meth)acrylate (B), additionally the photopolymerization initiator (C), and as necessary, the other components such as the silane-coupling agent, the UV absorber, and the antirust agent.

The adhesive composition [I] obtained as above is subjected to the adhesive sheet, specifically the adhesive sheet used for laminating the constituent member of the flexible image display device.

<Constitution>

The present adhesive sheet may be a single-layer sheet composed of only an adhesive layer formed from the adhesive composition [I] (also referred to as “the present adhesive layer”) or may be a multilayer sheet in which a plurality of the present adhesive layers is laminated.

<Physical Properties of the Present Adhesive Sheet>

The present adhesive sheet can have the following physical properties.

(Storage Shearing Elastic Modulus)

The present adhesive sheet has a storage shearing elastic modulus at −40° C. (G′(−40° C.)) obtained by measuring a dynamic viscoelasticity with a shearing mode at a frequency of 1 Hz of not greater than 1,200 kPa. The (G′(−40° C.)) is preferably not greater than 1,000 kPa, further preferably not greater than 950 kPa, further preferably not greater than 900 kPa, particularly preferably not greater than 850 kPa, and still further preferably not greater than 830 kPa. A lower limit of the storage shearing elastic modulus (G′(−40° C.)) of the present adhesive sheet is preferably not less than 50 kPa from the viewpoints of prevention of glue ooze and shape retention of the adhesive sheet.

The storage shearing elastic modulus (G′(−40° C.)) of the present adhesive sheet within the above range can reduce an interlayer stress in folding the laminated sheet or the flexible image display device member particularly from low temperature to high temperature where the present adhesive sheet is laminated to the member sheet to form the laminated sheet or the flexible image display device member, for example. Accordingly, delamination and cracking of the member sheet or the flexible member can be inhibited.

In the embodiment of the present disclosure, the storage elastic modulus of the adhesive sheet can be remarkably low even under a significantly low temperature environment of −40° C. Accordingly, the interlayer stress in folding the laminated sheet or the flexible image display device member where the flexible image display device member is formed can be reduced to exhibit excellent flexibility more than ever before.

In the present adhesive sheet, a storage shearing elastic modulus at −20° C. (G′(−20° C.)) obtained by measuring a dynamic viscoelasticity with a shearing mode at a frequency of 1 Hz is preferably not greater than 200 kPa, further preferably not greater than 150 kPa, further preferably not greater than 100 kPa, and still further preferably not greater than 90 kPa. A lower limit of the storage shearing elastic modulus (G′(−20° C.)) of the present adhesive sheet is preferably not less than 50 kPa, and further preferably not less than 87 kPa from the viewpoints of prevention of glue ooze and shape retention of the adhesive sheet.

In the present adhesive sheet, a ratio of the storage shearing elastic modulus at −40° C. (G′(−40° C.)) to the storage shearing elastic modulus at −20° C. (G′(−20° C.)), G′(−40° C.)/G′(−20° C.), is preferably not greater than 15, further preferably not greater than 12, and particularly preferably not greater than 10. The ratio of the storage shearing elastic moduli (G′(−40° C.)/G′(−20° C.)) within the above range can yield the adhesive sheet having small temperature dependency particularly in a low temperature region, and can yield the laminate having excellent durability causing no delamination when folded in a low temperature state (“low-temperature bending durability”).

The lower limit is typically 1 from the viewpoint of obtaining the adhesive sheet having the low temperature dependency.

In the present adhesive sheet, a storage shearing elastic modulus at 60° C. (G′(60° C.)) obtained by measuring a dynamic viscoelasticity with a shearing mode at a frequency of 1 Hz is preferably not greater than 100 kPa, further preferably not greater than 50 kPa, particularly preferably not greater than 30 kPa, and still further preferably not greater than 20 kPa in terms of obtaining high adhesiveness.

A lower limit of the storage shearing elastic modulus (G′(60° C.)) of the present adhesive sheet is preferably not less than 1 kPa from the viewpoints of prevention of glue ooze and shape retention of the adhesive sheet.

In the present adhesive sheet, a ratio of the storage shearing elastic modulus at −40° C. (G′(−40° C.)) to the storage shearing elastic modulus at 60° C. (G′(60° C.)), G′(−40° C.)/G′(60° C.), is preferably not greater than 200, specifically preferably not greater than 160, specifically further preferably not greater than 120, further preferably not greater than 100, and still more preferably not greater than 90. The ratio of the storage shearing elastic moduli (G′(−40° C.)/G′(60° C.)) within the above range can yield the adhesive sheet having small temperature dependency from a low temperature region to a high temperature region. Specifically, an interlayer stress in folding of the laminated sheet or the flexible image display device member can be reduced from low temperature to high temperature, which can inhibit delamination and cracking of the member sheet or the flexible member.

The lower limit is typically 1 from the viewpoint of obtaining the adhesive sheet having small temperature dependency.

(Loss Shearing Elastic Modulus) In the present adhesive sheet, a loss shearing elastic modulus at 23° C. (G″(23° C.)) obtained by measuring a dynamic viscoelasticity with a shearing mode at a frequency of 1 Hz is preferably not less than 8 kPa, further preferably not less than 10 kPa, and particularly preferably not less than 12 kPa. Meanwhile, an upper limit of the loss shearing elastic modulus (G″(23° C.)) is preferably not greater than 400 kPa from the viewpoint of reduction in stress in bending.

The loss shearing elastic modulus (G″(23° C.)) of the present adhesive sheet within the above range can further increase adhesiveness of the present adhesive sheet.

(Maximum Point of Loss Tangent (tan δ) and Glass Transition Temperature (Tg))

In the present adhesive sheet, a loss tangent (tan δ) obtained by measuring a dynamic viscoelasticity with a shearing mode at a frequency of 1 Hz preferably has a maximum point at preferably not higher than −35° C. The lower limit is typically −50° C.

This maximum point of the loss tangent (tan δ) can be interpreted as a glass transition temperature (Tg). The glass transition temperature (Tg) within the above range facilitates regulation of the storage shearing elastic modulus (G′(−40° C.)) of the present adhesive sheet to be not greater than 1,200 kPa.

When the loss tangent (tan δ) obtained by measuring a dynamic viscoelasticity with a shearing mode at a frequency of 1 Hz has only one observed inflection point, in other words, when the tan δ curve exhibits a single-peak shape, the glass transition temperature (Tg) can be considered to be single.

The “maximum point” of the loss tangent (tan δ) means a peak value in the tan δ curve, namely a point having a maximum value among inflection points where a differentiated value changes from positive (+) to negative (−) in a predetermined range or in an entire range.

The elastic moduli (storage shearing elastic moduli) G′ at various temperatures, the viscosity (loss shearing elastic modulus) G″, and tan δ=G″/G′ can be measured by using a strain rheometer.

The storage shearing elastic modulus (G′), the loss shearing elastic modulus (G″), and the loss tangent (tan δ) can be regulated within the above ranges by regulating types, weight average molecular weights, etc. of the components of the adhesive composition [I] (for example, the acrylic polymer (A) and the monofunctional (meth)acrylate (B)) constituting the present adhesive sheet, or further regulating a gel fraction, etc. of the adhesive sheet. The method for regulation is not limited to these methods.

(Recovering Ability)

A recovering rate of the present adhesive sheet can be measured by applying shearing strain corresponding to a seven-fold thickness at 25° C. for 10 minutes, and then reading a strain value (remained strain value) 1 minute or 10 minutes after the stress is removed. The recovering rate can be determined with the following formula.

Recovering rate (%)=[(700−Remained strain value)/700]×100

The present adhesive sheet having such a recovering rate has excellent recovering ability without remaining folding trace due to leaving in a bending state even when the present adhesive sheet adheres to the member sheet and when the present adhesive sheet is subjected to folding operation at low temperature or high temperature.

From such a viewpoint, the recovering rate is preferably not less than 40%, particularly preferably not less than 50%, further preferably not less than 70%, furthermore preferably not less than 75%, and still more preferably 80%, the recovering rate being calculated from remained strain values at 1 minutes and 10 minutes after applying shearing strain corresponding to a seven-fold thickness at 25° C. for 10 minutes and then removing a stress. Since a higher recovering rate is more preferable, the upper limit is 100%.

In the present adhesive sheet, a bifunctional (meth)acrylate monomer having an alkylene group with a certain length or more, specifically a di(meth)acrylate having an alkylene group having 5 to 20 carbon atoms is preferably used as the radical-polymerizable compound in order to obtain the good recovering ability.

In this case, the bifunctional (meth)acrylate having the alkylene group with a certain length or more bonds side chains of the acrylic polymer (A) to each other to strengthen intertwining between the polymer chains, which increases a difference in entropy before and after elongation to improve the recovering ability by entropic elasticity.

The method for regulating the recovering ability is not limited to these methods.

(Gel Fraction)

A gel fraction of the present adhesive sheet is preferably 30 to 95 wt. %, more preferably 50 to 90 wt. %, further preferably 55 to 85 wt. %, and particularly preferably 60 to 85 wt. %. The present adhesive sheet having a gel fraction not less than the above lower limit can sufficiently retain the shape. The present adhesive sheet having a gel fraction not greater than the upper limit can increase adhesiveness.

The gel fraction is an indicator of a crosslinking degree (degree of curing), and can be measured under measurement conditions in the Example, described later.

(Total Light Transmittance, Haze) A total light transmittance of the present adhesive sheet is preferably not less than 85%, further preferably not less than 88%, and more preferably not less than 90%.

A haze of the present adhesive sheet is preferably not greater than 1.0%, further preferably not greater than 0.8%, and particularly preferably not greater than 0.5%.

The present adhesive sheet having a haze of not greater than 1.0% can be used for an image display device.

For regulating the haze of the present adhesive sheet within the above range, the present adhesive sheet preferably contains no particles such as organic particles.

<Thickness>

A thickness of the present adhesive sheet is not particularly limited. The thickness of not less than 10 μm yields good handleability, and the thickness of not greater than 1,000 μm can contribute to thinning of the present adhesive sheet.

Thus, the thickness of the present adhesive sheet is preferably not less than 10 μm, more preferably not less than 15 μm, particularly preferably not less than 20 μm, and furthermore preferably not less than 25 μm.

The upper limit is preferably not greater than 1,000 μm, specifically preferably not greater than 500 μm, particularly preferably not greater than 250 μm, further preferably not greater than 100 μm, and still further preferably not greater than 50 μm.

<Preferable Use of the Present Adhesive Sheet>

The present adhesive sheet is used for laminating a member constituting a display (also referred to as “display member”), specifically a flexible member for a display used for producing the display. The present adhesive sheet is used as an adhesive part for the flexible display used for producing the flexible display.

The flexible member same as those described later can be used.

<Method for Manufacturing the Present Adhesive Sheet>

Next, a method for manufacturing the present adhesive sheet will be described.

The following description is an example of the method for manufacturing the present adhesive sheet, and the present adhesive sheet is not limited to the adhesive sheet manufactured by the following manufacturing method.

For producing the present adhesive sheet, the adhesive composition [I] for forming the present adhesive sheet containing the acrylic polymer (A), preferably further containing the monofunctional (meth)acrylate (B), the photopolymerization initiator (C), and other components as necessary is prepared, this adhesive composition [I] is formed into a sheet, and the sheet is subjected to crosslinking, namely a polymerization reaction to be cured and appropriately processed as necessary to produce the present adhesive sheet.

For producing the present adhesive sheet, the adhesive composition [I] for forming the present adhesive sheet is prepared in the same manner as above, this composition is applied on the member sheet or the flexible sheet, and this adhesive composition [I] is cured to form the present adhesive sheet. Note that the method is not limited to this method.

When the adhesive composition [I] for forming the present adhesive sheet is prepared, the raw materials may be kneaded by using a temperature-controllable kneader (for example, a uniaxial extruder, a biaxial extruder, a planetary mixer, a biaxial mixer, and a pressurizing kneader).

When the raw materials are mixed, the additives such as the silane-coupling agent and the antioxidant may be blended with the resin in advance and then supplied into the kneader, all the materials may be melt-mixed in advance and then supplied, or only the additives may be condensed into the resin in advance to produce a master batch and then supplied.

As the method for forming the adhesive composition [I] into a sheet, usable is a known method such as a wet-laminating method, a dry-laminating method, an extrusion casting method using a T-die, an extrusion laminating method, a calendar method, an inflation method, an injection molding method, and a liquid-injecting curing method. Among these, a wet-laminating method, an extrusion casting method, and an extrusion laminating method are preferable for manufacturing the sheet.

The adhesive composition [I] can be cured by irradiation with active energy radiation to manufacture a cured product. In addition to the irradiation with active energy radiation, heating may be performed for further curing. Specifically, the present adhesive sheet can be manufactured by irradiating a formed product of the adhesive composition [I], for example a sheet, with active energy radiation. In addition to the irradiation with active energy radiation, heating may be performed for further curing.

Irradiation energy, an irradiation time, an irradiation method, etc. of the active energy radiation are not particularly limited as long as the photopolymerization initiator (C) is activated to polymerize the monomer components.

When the hydrogen abstraction-type photopolymerization initiator is used as the photopolymerization initiator (C), the acrylic polymer (A) is also subjected to the hydrogen abstraction reaction and the acrylic polymer (A) is incorporated into the crosslinked structure, which can form a crosslinked structure with many crosslinking points.

Therefore, the present adhesive sheet is preferably a cured product produced by using the hydrogen abstraction-type photopolymerization initiator.

As another embodiment of the method for manufacturing the present adhesive sheet, the adhesive composition [I] can be dissolved in an appropriate solvent and coated by using various coating methods.

When the coating method is used, the present adhesive sheet can be obtained by thermal curing in addition to the curing by the aforementioned irradiation with the active energy radiation. In the case of coating, the thickness of the present adhesive sheet can be regulated by a coating thickness and a solid-content concentration of the coating liquid.

For example, the adhesive composition [I] is dissolved in a solvent, then coated on a release film and dried, and cured by irradiation with the active energy to form the present adhesive sheet. A release film may be further laminated as necessary. In this case, it is acceptable that the release film is coated and dried, the adhesive composition [I] is cured by irradiation with the active energy, and the release film may be laminated thereto. Alternatively, it is acceptable that the release film is coated and dried, the release film is laminated, and then the adhesive composition [I] is cured by irradiation with the active energy to form the present adhesive sheet.

Such a solvent is not particularly limited as long as the solvent dissolves the adhesive composition [I]. Examples of the solvent include: ester solvents, such as methyl acetate, ethyl acetate, methyl acetoacetate, and ethyl acetoacetate; ketone solvents, such as acetone, methyl ethyl ketone, and methyl isobutyl ketone; aromatic solvents, such as toluene and xylene; and alcohol solvents, such as methanol, ethanol, and propyl alcohol. These may be used alone, or two or more of these may be used in combination. Among these, ethyl acetate, acetone, methyl ethyl ketone, and toluene are preferable in terms of solubility, drying property, cost, etc., and ethyl acetate is particularly preferably used.

A content of the solvent is preferably not greater than 600 parts by weight, more preferably not greater than 500 parts by weight, further preferably not greater than 400 parts by weight, and particularly preferably not greater than 300 parts by weight relative to 100 parts by weight of the acrylic polymer (A) in terms of drying property. Meanwhile, the content is preferably not less than 1 part by weight, more preferably not less than 50 parts by weight, further preferably not less than 100 parts by weight, and particularly preferably not less than 150 parts by weight.

The coating can be performed by a commonly used method such as roll coating, die coating, gravure coating, comma coating, screen printing, and bar coating, for example.

A content of the solvent in the adhesive composition [I] after drying preferably not greater than 1 wt. %, more preferably not greater than 0.5 wt. %, particularly preferably not greater than 0.1 wt. %, and most preferably 0 wt. %.

The drying temperature is typically 40 to 150° C., more preferably 45 to 140° C., further preferably 50 to 130° C., and particularly preferably 55 to 120° C. The above temperature range can efficiently and relatively safely remove the solvent while inhibiting thermal deformation of the release film.

The drying time is typically 1 to 30 minutes, more preferably 3 to 25 minutes, and further preferably 5 to 20 minutes. The above time range can efficiently and sufficiently remove the solvent.

Examples of the drying method include drying with a drying apparatus or a heat roller, and drying by blowing hot air to the film. Among these, a drying apparatus is preferably used in terms of uniform and easy drying. These may be used alone, or two or more of these may be used in combination.

Examples of the active energy radiation in the irradiation with active energy include: rays, such as far UV, UV, near UV, infrared ray, and visible ray; and ionizing radiations, such as X-ray, α-ray, β-ray, γ-ray, electron beam, proton beam, and neutron beam. Among these, UV is preferable from the viewpoints of reduction in damage of constituent members of an optical apparatus and reaction control. In addition, curing with UV radiation is advantageous in terms of a curing rate, easy availability of the irradiation apparatus, cost, etc.

Examples of a light source of the UV radiation include a high-pressure mercury lamp, an ultrahigh-pressure mercury lamp, a low-pressure mercury lamp, a carbon arc lamp, a metal halide lamp, a xenon lamp, a chemical lamp, an electrodeless discharge lamp, and an LED, which emit light with a wavelength region of 150 to 450 nm. Among these, a high-pressure mercury lamp is preferably used.

The radiation is performed under a condition of a radiation dose (integrated light quantity) of active energy ray of preferably 30 to 3,000 mJ/cm², more preferably 100 to 2,000 mJ/cm², and further preferably 300 to 1,500 mJ/cm² in terms of curing.

After the active energy radiation, heating can be performed as necessary to increase curing degree.

On at least one surface of the adhesive sheet obtained above, a release film can be provided from the viewpoint of prevention of blocking and prevention of foreign matter adhesion.

As such a release film, known release films can be appropriately used.

As a material of the release film, a film, such as a polyester film, a polyolefin film, a polycarbonate film, a polystyrene film, an acryl film, a triacetylcellulose film, and a fluororesin film, subjected to a releasing treatment by applying a silicone resin; and release paper can be appropriately selected for use. These materials can be appropriately selected for use.

A thickness of the release film is not particularly limited. Specifically, the thickness is preferably 10 to 250 μm, more preferably 25 to 200 μm, and further preferably 35 to 190 μm from the viewpoints of, for example, processability and handleability.

As necessary, an emboss process or other texturing process (such as a corn or pyramid shape, or a hemispherical shape) may be performed. For a purpose of improving adhesiveness to each member sheet, the surface may be subjected to surface treatments such as a corona treatment, a plasma treatment, and a primer treatment.

The present adhesive sheet can be provided as an adhesive sheet with the release film by laminating the release film onto one surface or both surfaces of the adhesive layer (the present adhesive sheet) composed of the adhesive composition [I].

<<The Present Laminated Sheet>>

A laminated sheet according to an example of the embodiment of the present disclosure (hereinafter, which may be referred to as “the present laminated sheet”) is a sheet comprising the present adhesive sheet and another layer. In the layers constituting the present laminated sheet, a thickness of the present adhesive sheet preferably accounts for 10 to 90%, more preferably not less than 20% and not greater than 80%, further preferably not less than 30% and not less than 70%, in a total thickness of the present laminated sheet. The present laminated sheet is preferably: a laminate comprising a member sheet on at least one surface of the present adhesive sheet; or a laminate comprising the present adhesive sheet on at least one surface of a member sheet.

The present laminated sheet is preferably a laminated sheet comprising constitution in which a member sheet (hereinafter, which may be also referred to as “the first member sheet”), the present adhesive sheet, and a member sheet other than the above (hereinafter, which may be also referred to as “the second member sheet”) are laminated in this order, for example.

The present laminated sheet can be produced by adhering the present adhesive sheet to the first member sheet and/or the second member sheet. However, the manufacturing method is not limited thereto.

The first member sheet and the second member sheet may be same as or different from each other.

<Member Sheet>

Examples of the member sheet (encompassing “the first member sheet” and/or “the second member sheet”) constituting the present laminated sheet, that is, the member sheet to adhere to the present adhesive sheet include: a resin sheet containing, as a main component, at least one resin selected from the group consisting of a polyester resin, a cycloolefin resin, a triacetylcellulose resin, a polymethyl methacrylate resin, an epoxy resin, a polyimide resin, an aramid resin, and a polyurethane resin; or glass such as thin-film glass. Here, the thin-film glass refers to glass having a thickness of the aforementioned member sheet.

Among these, the resin sheet containing a cycloolefin resin as a main component has a tensile strength at 25° C. (ASTM D882) of as low as 40 to 60 MPa with a thickness of 100 μm. A laminated sheet using such a member sheet having a low tensile strength easily cracks in folding, leading to difficulty in solving the cracking in the range of conventional art.

As the member sheet, conventionally known sheets can be used. Examples thereof preferably include, but not limited to, the following.
PET film “S100, available from Mitsubishi Chemical Corporation, thickness: 50 μm” (tensile strength: 73 MPa)
PEN film “FS205S, available from TEIJIN LIMITED, thickness: 50 μm” (tensile strength: 193 MPa)
CPI film “C_50, available from Kolon Industries, Inc., thickness: 53 μm” (tensile strength: 204 MPa)

The term “main component” refers to a component accounting for the highest weight proportion in the resin components constituting the member sheet. Specifically, the main component accounts for not less than 50 wt. %, preferably not less than 55 wt. %, and further preferably not less than 60 wt. %, in the member sheet or the resin composition forming the member sheet.

Although depending on the constitution of the flexible image display device and the position of the present adhesive sheet, examples of the first member sheet and the second member sheet include a cover lens, a polarizing plate, a retardation film, a barrier film, a touch-sensor film, and a light emitting element.

In particular, the first member sheet preferably has a touch input function with considering the constitution of the image display. When the present laminated sheet has the aforementioned second member sheet, the second member sheet may also have a touch input function.

(Tensile Strength at 25° C.)

Furthermore, the first member sheet has a tensile strength at 25° C. measured in accordance with ASTM D882 (also referred to as “25° C. tensile strength (ASTM D882)”) of preferably 10 to 900 MPa, more preferably not less than 15 MPa and not greater than 800 MPa, and further preferably not less than MPa and not greater than 700 MPa.

The first member sheet having the 25° C. tensile strength (ASTM D882) within the above range is preferable because the first member sheet hardly cracks even in bending.

When the present laminated sheet has the aforementioned second member sheet, the second member sheet has a tensile strength at 25° C. measured in accordance with ASTM D882 of preferably 10 to 900 MPa, more preferably not less than 15 MPa and not greater than 800 MPa, and further preferably not less than 20 MPa and not greater than 700 MPa.

The second member sheet having the 25° C. tensile strength (ASTM D882) within the above range is preferable because the first member sheet hardly cracks even in bending.

Specifically, both of the first member sheet and the second member sheet preferably have the tensile strength at 25° C. measured in accordance with ASTM D882 of 10 to 900 MPa.

The first member sheet and the second member sheet may be composed of the same material, or may be composed of different materials.

Examples of the member sheet (encompassing the first member sheet and the second member sheet) having high tensile strength include a polyimide film and a polyethylene naphthalate (PEN) film. These films typically have a tensile strength of not greater than 900 MPa. The lower limit is typically 50 MPa.

On the other hand, examples of the member sheet having a rather low tensile strength include a polyethylene terephthalate (PET) film, a triacetylcellulose (TAC) film, and a cycloolefin polymer (COP) film. These films typically have a tensile strength of not less than 10 MPa. The upper limit is typically 200 MPa.

The present laminated sheet can inhibit defects such as cracking by the action of the present adhesive sheet even when the present laminated sheet has such a member sheet composed of the material having a rather low tensile strength.

<Physical Properties of the Present Laminated Sheet>

The present laminated sheet can have the following physical properties.

(Adhesive Force)

The present laminated sheet has an adhesive force (peeling angle: 180°, peeling rate: 300 mm/min) to the member sheet of the present adhesive sheet of preferably 0.5 to 30 N/cm, more preferably 1 to 20 N/cm, and further preferably 3 to 10 N/cm. Within such a range, a sufficient adhesive force can be exhibited, and the present laminated sheet tends to be preferably used as the adhesive sheet for the flexible image display device.

(Dynamic Bending Durability)

As for a reliability test of dynamic bending (dynamic bending durability) of the present laminated sheet, a number of bending at which defects of a bending portion (delamination, breakage, buckling, and floating) do not occur is preferably not less than 100,000, and more preferably not less than 200,000. The number of bending is determined with a U-shape bending cycle evaluation with setting of a curvature radius R=1.5 mm, 60 rpm (1 Hz), −20° C.

(Static Bending Durability)

As for a reliability test of static bending (static bending durability) of the present laminated sheet, a storage time in which defects of a bending portion (delamination, breakage, buckling, and floating) do not occur is preferably not shorter than 24 hours, and more preferably not shorter than 120 hours. The storage time is determined with keeping a bending state with a curvature radius R=1.5 mm, −20° C.

The above dynamic and static bending durability tests can be performed under measurement conditions in Example, described later.

<Thickness of the Present Laminated Sheet>

A thickness of the present laminated sheet is not particularly limited. For example, the present laminated sheet is, as an example, a sheet when used for an image display device. A thickness of the sheet of not less than 0.01 mm yields good handleability, and the thickness of not greater than 1 mm can contribute to thinning of the present laminated sheet.

Therefore, the thickness of the present laminated sheet is preferably not less than 0.01 mm, further preferably not less than 0.03 mm, and particularly preferably not less than 0.05 mm.

Meanwhile, the upper limit is preferably not greater than 1 mm, further preferably not greater than 0.7 mm, and particularly preferably not greater than 0.5 mm.

<Method for Manufacturing the Present Laminated Sheet>

Next, a method for manufacturing the present laminated sheet will be described.

The following description is an example of the method for manufacturing the present laminated sheet, and the present laminated sheet is not limited to those manufactured by the following manufacturing method.

The present laminated sheet may be manufactured by preparing the adhesive composition [I] as in the method for manufacturing the present adhesive sheet, and applying and curing this adhesive composition [I] on the first member sheet and/or the second member sheet, for example, for forming the adhesive sheet.

In this case, the method for preparing the adhesive composition [I], the coating method, the method for curing the adhesive composition [I], etc. are same as those in the method for manufacturing the present adhesive sheet.

Alternatively, the present adhesive sheet may be manufactured in advance and laminated to the first member sheet and/or the second member sheet to manufacture the present laminated sheet.

For a purpose of improving the adhesiveness, each of surfaces of the present adhesive sheet, the first member sheet, and the second member sheet may be subjected to surface treatments such as a corona treatment, a plasma treatment, and a primer treatment.

When the present laminated sheet has the constitution in which the member sheet is laminated to only one surface of the present adhesive sheet, a protective film with a laminated release layer can be provided on the other surface of the present adhesive sheet, the member sheet being not laminated to the other surface.

<The Present Flexible Image Display Device Member>

A flexible image display device member according to an example of the embodiment of the present disclosure (hereinafter, which may be referred to as “the present flexible image display device member”) is a flexible image display device member having constitution in which two flexible members are laminated via the present adhesive sheet.

Among constituent elements in the present flexible image display device member, the present adhesive sheet is same as above. Elements other than the adhesive sheet will be described hereinafter.

(Flexible Member)

Examples of the flexible member constituting the present flexible image display device member include: flexible displays, such as an organic electroluminescence (EL) display; and flexible members for a display, such as a cover lens (cover film), a polarizing plate, a polarizer, a retardation film, a barrier film, a viewing-angle compensating film, a luminescence improving film, a contrast improving film, a diffusing film, a semitransparent reflective film, an electrode film, a transparent conductive film, a metal mesh film, and a touch sensor film. Two of any one or two of them may be used in combination. Examples of the combination include: a combination of a flexible display and another flexible member; and a combination of a cover lens and another flexible member.

The flexible member means a bendable member, specifically a repeatedly bendable member. The flexible member is preferably a member fixable in a curved shape with a curvature radius of not greater than 5 mm, particularly not greater than 3 mm, and more preferably a member durable for repeated bending actions with a curvature radius of not greater than 1.5 mm.

In the aforementioned constitution, examples of a main component in the flexible member include a resin sheet and glass.

Examples of a material of such a resin sheet include polyester resin, cycloolefin resin, triacetylcellulose resin, polymethyl methacrylate resin, polyurethane, epoxy resin, polyimide resin, and aramid resin. The material may be one resin or two or more resins. Among these, the resin sheet preferably contains, as a main component, at least one resin selected from the group consisting of polyester resin, cycloolefin resin, triacetylcellulose resin, polymethyl methacrylate resin, epoxy resin, polyimide resin, aramid resin, and polyurethane resin.

Here, “the main component” refers to a component accounting for the highest weight proportion in components constituting the flexible member. Specifically, the main component accounts for preferably not less than 50 wt. %, further preferably not less than 55 wt. %, and particularly preferably not less than 60 wt. %, in the resin composition (resin sheet) forming the flexible member. The flexible member may be composed of thin-film glass.

In the aforementioned constitution, any one of the two flexible members, namely a first flexible member, preferably has a tensile strength at 25° C. measured in accordance with ASTM D882 of 10 to 900 MPa, particularly preferably not less than 15 MPa and not greater than 800 MPa, and further preferably not less than 20 MPa and not greater than 700 MPa.

The other flexible member, namely a second flexible member, preferably has a tensile strength at 25° C. measured in accordance with ASTM D882 of 10 to 900 MPa, particularly preferably not less than 15 MPa and not greater than 800 MPa, and further preferably not less than 20 MPa and not greater than 700 MPa.

The other flexible member having a tensile strength at 25° C. (ASTM D882) within the above range is preferable because the flexible member hardly cracks even in bending.

Examples of the flexible member having a high tensile strength include a polyimide film, a polyester film, and an aramid film. The tensile strength of these films is typically not greater than 900 MPa.

On the other hand, the flexible member having a rather low tensile strength include a triacetylcellulose (TAC) film and a cycloolefin polymer (COP) film. The tensile strength of these films is typically not less than 10 MPa.

The present flexible image display device member even with such a flexible member composed of the material having a rather low tensile strength can inhibit defects such as cracking by the action of the present adhesive sheet.

<Method for Manufacturing the Present Flexible Image Display Device Member>

A method for manufacturing the present flexible image display device is not particularly limited. The adhesive composition [I] may be applied on the flexible member to form the adhesive sheet as noted above, or the adhesive sheet may be formed in advance by using the adhesive composition [I] and then laminated to the flexible member.

<<The Present Flexible Image Display Device>>

A flexible image display device according to an example of the embodiment of the present disclosure (hereinafter, which may be referred to as “the present flexible image display device”) is an image display device in which the present laminated sheet or the present flexible image display device member is integrated. For example, the present flexible image display device having the present laminated sheet can be formed by laminating the present laminated sheet to another image display device constituent member.

The term “flexible image display device” refers to an image display device that leaves no folding trace even with repeated folding, that can quickly recover to the state before folding when releasing the folding, and that can display a strain-free image even in folding.

More specific examples thereof include an image display device composed of a member fixable in a curved shape with a curvature radius of not greater than 5 mm, particularly not greater than 3 mm, and more preferably a member durable for repeated bending actions with a curvature radius of not greater than 1.5 mm.

The present laminated sheet can prevent delamination and cracking of the laminated sheet even with folding operation under a high temperature environment, and has good recovering ability. Therefore, it is one feature of the present laminated sheet that the flexible image display device having excellent flexibility can be produced.

### EXAMPLES

Hereinafter, the embodiment of the present disclosure will be more specifically described with Examples, but the embodiment of the present disclosure is not limited to the following Examples as long as it does not depart from the spirit thereof.

In Examples, “parts” and “%” mean those on a weight basis.

<Raw Material>

First, an acrylic polymer and adhesive composition prepared in Examples and Comparative Examples will be described in detail.

<Acrylic Polymer (A)>

Acrylic Polymers (1) to (5) were prepared with copolymerization component formulations as shown in Table 1.

TABLE 1

| | | | | | | | | Weight | |
|---|---|---|---|---|---|---|---|---|---|
| | Copolymerization components | | | | | | | average | Glass |
| | | | | | | | Monofunctional | molecular | transition |
| Acrylic | n-OA | BA | 2EHA | EMA | 2HEA | 4HBA | (meth)acrylate | weight | temperature |
| polymer | (pars) | (parts) | (parts) | (parts) | (parts) | (parts) | (B) (parts) | (Mw) | (Tg) (°C) |
| (1) | 80 | — | — | — | — | 20 | — | 770,000 | −38° C. |
| (2) | — | 15 | 60 | 5 | 20 | — | — | 770,000 | −27° C. |
| (3) | 76.2 | — | — | — | — | 19.0 | 4.8 | 800,000 | −43° C. |
| (4) | — | 80 | — | — | — | 20 | — | 800,000 | −35° C. |
| (5) | | 31 | 46 | | | 23 | | 800,000 | −39° C. |

<Monofunctional (Meth)acrylate (B)>
Propylene glycol skeleton-containing monofunctional urethane acrylate, PEM-X264 (available from AGC Inc.), weight average molecular weight: approximately 10,000, glass transition temperature: −53° C.

<Photopolymerization Initiator (C)>
Esacure TZT (available from IGM, mixture of 4-methylbenzophenone and 2,4,6-trimethylbenzophenone (hydrogen abstraction type))

### Examples 1 to 8 and Comparative Examples 1 to 3

The acrylic polymer, the monofunctional (meth)acrylate, the photopolymerization initiator, and ethyl acetate as a solvent were uniformly mixed in a blending formulation as shown in Table 2 to obtain an adhesive composition solution (solid content concentration: 33%).

TABLE 2

| | | | | | | | | integrated | |
|---|---|---|---|---|---|---|---|---|---|
| | Acrylic polymer (A) | | | | | Monofunctional | | light | |
| | (1) | (2) | (3) | (4) | (5) | (meth)acrylate | Photopolymerization | quantity | Thickness |
| | (parts) | (parts) | (parts) | (parts) | (parts) | (B) (parts) | initiator (C) (parts) | (mJ/cm²) | (μm) |
| Ex. 1 | 100 | — | — | — | — | 5 | 3 | 900 | 50 |
| Ex. 2 | 100 | — | — | — | — | 5 | 3 | 900 | 25 |
| Ex. 3 | 100 | — | — | — | — | 10 | 3 | 900 | 50 |
| Ex. 4 | 100 | — | — | — | — | 20 | 3 | 900 | 50 |
| Ex. 5 | 100 | — | — | — | — | 40 | 3 | 900 | 50 |
| Ex. 6 | 100 | | — | — | — | 0 | 3 | 600 | 50 |
| Ex. 7 | — | 100 | — | — | — | 75 | 2 | 800 | 50 |
| Ex. 8 | — | — | 100 | — | | 0 | 3 | 400 | 50 |
| Comp. | — | | — | 100 | — | 0 | 3 | 600 | 50 |
| Ex. 1 | | | | | | | | | |
| Comp. | — | | — | 100 | — | 10 | 3 | 300 | 50 |
| Ex. 2 | | | | | | | | | |
| Comp. | | | | | 100 | 0 | 3 | 600 | 50 |
| Ex. 3 | | | | | | | | | |

The adhesive composition solution was applied on a release film (available from Mitsubishi Chemical Corporation, silicone-release treated polyester film, thickness: 100 μm) so that a thickness after drying was 50 μm (Examples 1 and 3 to 8 and Comparative Examples 1 to 3) or 25 μm (Example 2). After the applying, the coating was placed in a drying apparatus heated to a temperature of 90° C. and retained for 7 minutes to evaporate the solvent contained in the adhesive composition to dryness.

Furthermore, on a surface of the solvent-dried adhesive composition, a release film (available from Mitsubishi Chemical Corporation, silicone-release treated polyester film, thickness: 75 μm) was laminated to form a laminate. The adhesive composition was irradiated with UV through the release film by using a high-pressure mercury lamp (see Table 2 for each irradiation dose) to obtain an adhesive sheet laminate (an adhesive sheet with a release film).

The obtained adhesive sheet laminates were subjected to the following evaluation.

<Gel Fraction>

The release film was removed from each of the adhesive sheet laminates produced in Examples and Comparative Examples, and a plurality of the adhesive sheets was laminated to form a laminate with 1.0 mm in thickness. Then, the laminate was punched to a cylinder with 8 mm in diameter to form a sample, and this sample was wrapped with a 200-mesh SUS metal net, and immersed in ethyl acetate adjusted to 23° C. for 72 hours. Thereafter, the sample was dried at 75° C. for 4.5 hours, weights of the adhesive before and after the immersion in ethyl acetate were each measured, and a difference between the weights was specified as a weight of an insoluble adhesive remained in the metal net. A weight percentage of the insoluble adhesive remained in the metal net relative to the weight of the adhesive before the immersion in ethyl acetate was calculated as a gel fraction (%).

<Flexibility>

As evaluation of flexibility, a dynamic viscoelasticity of the adhesive sheet was measured, and a maximum temperature of a loss tangent (tan δ) (glass transition temperature: Tg) and storage shearing elastic moduli (G′) at −40° C., −20° C., and 60° C. were read from the results.

[Loss Tangent (tan δ) and Storage Shearing Elastic Moduli (G′)]

The release film was removed from each of the adhesive sheet laminates produced in Examples and Comparative Examples, and a plurality of the adhesive sheets was laminated to form a laminate with 1.0 mm in thickness.

The obtained laminate of the adhesive sheet (adhesive layer) was punched to a cylinder with 8 mm in diameter (height: 1.0 mm) to form a sample.

Temperature dispersion of dynamic viscoelasticity of the sample was measured by using a viscoelasticity measuring apparatus (trade name: “DHR 2” available from T.A. Instruments) under the following measurement conditions.

From the obtained temperature dispersion data of dynamic viscoelasticity, a peak temperature of the loss tangent (tan δ) (glass transition temperature (Tg)), the storage shearing elastic modulus at −40° C. G′(−40° C.), the storage shearing elastic modulus at −20° C. G′(−20° C.), and the storage shearing elastic modulus at 60° C. G′(60° C.) were read.

From the read values of the storage shearing elastic moduli (G′), the ratio of the storage shearing elastic modulus at −40° C. G′(−40° C.) to the storage shearing elastic modulus at −20° C. G′(−20° C.), G′(−40° C.)/G′(−20° C.); and the ratio of the storage shearing elastic modulus at −40° C. G′(−40° C.) to the storage shearing elastic modulus at 60° C. G′(60° C.), G′(−40° C.)/G′(60° C.) were calculated.

(Measurement Conditions)
Measurement tool: Φ 8 mm parallel plate
Strain: 0.1%
Frequency: 1 Hz
Measurement temperature: −60 to 100° C.
Temperature raising rate: 5° C./min

<Recovering Ability>

The release film was removed from each of the adhesive sheet laminates produced in Examples and Comparative Examples, and a plurality of the adhesive sheets was laminated to form a laminate with 1.0 mm in thickness.

The obtained laminate of the adhesive sheet (adhesive layer) was punched to a cylinder with 8 mm in diameter (height: 1.0 mm) to form a sample.

A recovering rate of the sample was measured by using a viscoelasticity measuring apparatus (trade name: “DHR 2” available from T.A. Instruments) under the following measurement conditions.

That is, shearing strain corresponding to a seven-fold thickness was applied at 25° C. with keeping for 10 minutes, and then a remained strain value 10 minutes after the stress was removed was read to measure the recovering rate.

The recovering rate can be determined with the following formula.

Recovering rate (%)=[(700−Remained strain value)/700]×100

<Bending Durability>

The release film was removed from each of the adhesive sheet laminates produced in Examples and Comparative Examples, and CPI films (main component: transparent polyimide, available from Kolon Industries, Inc., “C_50,” tensile strength: 204 MPa) were laminated to both the surfaces of the adhesive sheet by a hand roller, and cut to 5×10 cm to obtain a laminated sheet (sample) for bending durability.

The laminated sheet (sample) produced as above was used and evaluated as follows.

(Dynamic Bending Durability)

The laminated sheet (sample) was subjected to a U-shape bending cycle evaluation by using a durable system in a thermostatic and humidistatic chamber and using a face-shape unloaded U-shape expansion tester (available from Yuasa System Co., Ltd.) with setting of a curvature radius R=1.5 mm at 60 rpm (1 Hz). After the sample was left to stand at −20° C. for 3 hours, the sample was evaluated at the same temperature with 200,000 cycles. The evaluation was performed with the following evaluation criteria.
A: None of delamination, breakage, buckling, or floating occurred in a bending portion.
B: Any of delamination, breakage, buckling, or floating occurred in a bending portion.

(Static Bending Durability)

The laminated sheet (sample) was left to stand at −20° C. for 3 hours, then bent with the CPI film side as the inside and with a curvature radius R=1.5 mm, and left to stand at the same temperature. After 24 hours, the tool was opened and the static bending durability was evaluated by a recovered interior angle 1 hour later at a room temperature (23° C.). The recovered interior angle was observed and evaluated with the following evaluation criteria. A recovered interior angle of only the member sheet (CPI film) was similarly observed, and the interior angle of the film was 150°.
A: The interior angle of the bending portion was recovered to not less than 150°.
B: The interior angle of the bending portion was recovered to less than 1500.

Table 3 shows the results obtained by the above measurements and evaluations.

TABLE 3

| | | | | | | | | | Bending | |
|---|---|---|---|---|---|---|---|---|---|---|
| | | | | | | | | Recovering | durability | |
| | | | | | | | | ability | Dynamic | |
| | | Loss tangent (tanδ) and storage | | | | | | Recovering | bending | Static |
| | | shearing elastic moduli (G′) | | | | | | rate | test at | bending |
| | | Glass | | | | G′ | G′ | after | −20° C. | test at |
| | Gel | transition | G′ | G′ | G′ | (−40° C.)/ | (−40° C.)/ | 10 | for | −20° C. |
| | Fraction | temperature | (−40° C.) | (−20° C.) | (60° C.) | G′ | G′ | minutes | 200,000 | for |
| | (%) | (Tg) (° C.) | (kPa) | (kPa) | (kPa) | (−20° C.) | (60° C.) | (%) | times | 24 hrs |
| Ex. 1 | 70 | −40.4 | 824 | 88 | 9 | 9.4 | 92 | 83 | A | A |
| Ex. 2 | 70 | −40.4 | 824 | 88 | 9 | 9.4 | 92 | 83 | A | A |
| Ex. 3 | 71 | −41.1 | 753 | 83 | 10 | 9.1 | 79 | 83 | A | A |
| Ex. 4 | 73 | −45.4 | 561 | 75 | 9 | 7.5 | 64 | 89 | A | A |
| Ex. 5 | 75 | −48.6 | 379 | 67 | 10 | 5.7 | 39 | 82 | A | A |
| Ex. 6 | 64 | −38.0 | 1,001 | 86 | 6 | 11.6 | 167 | 81 | A | A |
| Ex. 7 | 66 | −45.0 | 944 | 125 | 17 | 7.6 | 56 | 79 | A | A |
| Ex. 8 | 77 | −43.4 | 751 | 102 | 15 | 7.4 | 51 | 85 | A | A |
| Comp. | 62 | −35.0 | 14,449 | 240 | 17 | 60.2 | 850 | 87 | A | B |
| Ex. 1 | | | | | | | | | | |
| Comp. | 46 | −38.9 | 1,960 | 132 | 12 | 14.8 | 163 | 53 | A | B |
| Ex. 2 | | | | | | | | | | |
| Comp. | 74 | −39.0 | 1,644 | 170 | 25 | 9.7 | 66 | 83 | A | B |
| Ex. 3 | | | | | | | | | | |

<Biomass Degree>

The adhesive sheet of Example 1 was subjected to a radiocarbon concentration measurement (¹⁴C biomass degree measurement) by using a ¹⁴C-AMS dedicated device (available from NEC Corporation) based on a tandem accelerator. The biomass degree determined in accordance with the bio-base concentration test standard ASTM D6866-21 was 57%.

From the above evaluation results, using the acrylic polymer containing a relatively long linear or branched alkyl group and a hydroxy group as the adhesive composition can remarkably reduce the storage elastic modulus at a significantly low temperature of −40° C. while having the adhesiveness to the adherend and achieving the recovering ability of the adhesive sheet. Accordingly, the adhesive sheet having excellent flexibility can be obtained.

Therefore, the flexible image display device using the present adhesive sheet is demonstrated to have excellent reliability of the recovering ability and the flexibility.

In addition, the adhesive sheet of Example 1, in which n-octyl acrylate (biomass degree: 72%) being a plant-derived (meth)acrylate was used, had a high biomass degree, and was the adhesive sheet excellent in terms of global environment protection.

The specific embodiments of the present disclosure have been demonstrated in the above Examples, but the above Examples are merely examples and should not be limitedly interpreted. Various modifications obvious to a person skilled in the art are intended to be included within the scope of the present disclosure.

### INDUSTRIAL APPLICABILITY

The adhesive sheet of the embodiment of the present disclosure has excellent flexibility at low temperature and excellent recovering ability. Therefore, the adhesive sheet of the embodiment of the present disclosure is useful as the adhesive sheet for yielding various flexible image display devices such as bendable, foldable, rollable, and stretchable devices, and specifically suitable for the adhesive sheet for a foldable image display device with repeated folding.

1. An adhesive sheet formed from an adhesive composition [I]containing an acrylic polymer (A), wherein
the acrylic polymer (A) has a structural portion derived from a compound (a1) represented by (Formula 1) and a structural portion derived from a hydroxy group-containing (meth)acrylate (a2), and
the adhesive sheet has a storage shearing elastic modulus (G′) at −40° C. of not greater than 1,200 kPa,
CH₂═CH(R₁)—COO(R₂) (Formula 1)
wherein R₁ represents a hydrogen atom or a methyl group, and R₂ represents a linear or branched alkyl group having 5 to 20 carbon atoms.

2. The adhesive sheet according to claim 1, wherein the adhesive composition [I] contains a monofunctional (meth)acrylate (B).

3. The adhesive sheet according to claim 1, wherein the acrylic polymer (A) has a weight average molecular weight of 600,000 to 1,500,000.

4. The adhesive sheet according to claim 2, wherein the monofunctional (meth)acrylate (B) has a glycol skeleton.

5. The adhesive sheet according to claim 2, wherein the monofunctional (meth)acrylate (B) is a urethane (meth)acrylate.

6. The adhesive sheet according to claim 2, wherein the monofunctional (meth)acrylate (B) is contained by 0.1 to 45 parts by weight relative to 100 parts by weight of the acrylic polymer (A).

7. The adhesive sheet according to claim 1, wherein the adhesive composition [I] contains a photopolymerization initiator (C).

8. The adhesive sheet according to claim 1, further comprising n-octyl (meth)acrylate.

9. The adhesive sheet according to claim 1, wherein the adhesive sheet has a biomass degree of not less than 40%.

10. The adhesive sheet according to claim 1, wherein the adhesive sheet has a storage shearing elastic modulus at −40° C. G′(−40° C.) of not greater than 1,000 kPa.

11. The adhesive sheet according to claim 1, wherein the adhesive sheet has a storage shearing elastic modulus at 60° C. G′(60° C.) of not less than 1 kPa and not greater than 100 kPa.

12. The adhesive sheet according to claim 1, wherein the adhesive sheet has a ratio of a storage shearing elastic modulus at −40° C. G′(−40° C.) to a storage shearing elastic modulus at −20° C. G′(−20° C.), G′(−40° C.)/G′(−20° C.), of not greater than 15.

13. The adhesive sheet according to claim 1, wherein the adhesive sheet has a ratio of a storage shearing elastic modulus at −40° C. G′(−40° C.) to a storage shearing elastic modulus at 60° C. G′(60° C.), G′(−40° C.)/G′(60° C.), of not greater than 200.

14. The adhesive sheet according to claim 1, wherein the adhesive sheet has a glass transition temperature (Tg) of not higher than −35° C., the glass transition temperature (Tg) being defined by a maximum value of a loss tangent (Tan δ) obtained by measuring a dynamic viscoelasticity.

15. The adhesive sheet according to claim 1, wherein the adhesive sheet has a recovering rate of not less than 75%, the recovering rate being calculated from a remained strain value at 10 minutes after applying shearing strain corresponding to a seven-fold thickness at 25° C. to the adhesive sheet with keeping for 10 minutes and then removing a stress.

16. The adhesive sheet according to claim 15, wherein the adhesive sheet has the recovering rate of not less than 80%.

17. The adhesive sheet according to claim 1, wherein the adhesive sheet has a gel fraction of 30 to 95 wt. %.

18. The adhesive sheet according to claim 1, wherein the adhesive sheet is used for laminating a constituent member of a flexible image display device.

19. A laminated sheet, comprising a member sheet having a tensile strength at 25° C. measured in according with ASTM D882 of 10 to 900 MPa on at least one surface of the adhesive sheet according to claim 1.

20. A laminated sheet, comprising the adhesive sheet according to claim 1 on at least one surface of a member sheet having a tensile strength at 25° C. measured in according with ASTM D882 of 10 to 900 MPa.

21. The laminated sheet according to claim 19, wherein the member sheet is: a resin sheet containing at least one resin selected from the group consisting of a polyester resin, a cycloolefin resin, a triacetylcellulose resin, a polymethyl methacrylate resin, an epoxy resin, a polyimide resin, an aramid resin, and a polyurethane resin as a main component; or glass.

22. A flexible image display device, comprising the laminated sheet according to claim 19.
